(19) United States
(12) Patent Application Publication
(10) Pub. No.: US 2010/0089432 A1
(43) Pub. Date: Apr. 15, 2010

(54) PHOTOVOLTAIC MODULE COMPRISING LAYER WITH CONDUCTING SPOTS

(75) Inventors: Gerrit Cornelis Dubbeldam, Zevenaar (NL); Edwin Peter Sportel, Arnhem (NL)

Correspondence Address: OLIFF & BERRIDGE, PLC, P.O. BOX 320850, ALEXANDRIA, VA, 22320-4850, US

(73) Assignee: Helianthos B.V., Arnhem (NL)

(21) Appl. No.: 12/450,600

(22) PCT Filed: Apr. 23, 2008
(86) PCT No.: PCT/EP2008/054896

§ 371 Date: Dec. 22, 2009

(30) Foreign Application Priority Data
Apr. 26, 2007 (EP) 07107029.6

(51) Int. Cl. H01L 31/042; H01L 31/18; H01L 21/26

(52) U.S. Cl. 136/244; 438/73; 257/E21.328

(57) ABSTRACT

The invention pertains to a photovoltaic (PV) module comprising a plurality of cells, each cell containing a substrate, a transparent conductor layer, a photovoltaic layer, and a back-electrode layer, wherein the photovoltaic layer comprises at least one p-i-n or n-i-p silicon layer, characterized in that said silicon layer comprises 10 to 1000 conducting spots of recrystallized silicon per cm², each having independently a surface or 10 to 2500 μm. The PV module can be obtained by a method wherein the p-i-n or n-i-p silicon layer is locally heated whereby said silicon is transformed at these spots, after which the silicon at these spots is allowed to solidify in a transformed state.

The invention relates to a photovoltaic (PV) module comprising a plurality of cells, each cell containing a substrate, a transparent conductor layer, a photovoltaic layer, and a back-electrode layer, wherein the photovoltaic layer comprises at least one p-i-n or n-i-p silicon layer, and to a method of making said photovoltaic module.

When a PV module consisting of many series connected cells is partly shaded, the illuminated cells may cause a strong negative (reverse) voltage over the shaded cells. That is particularly the case when the shaded cells have a high parallel resistance. Because no current is generated in the shaded cells, the module current is almost zero so that the shaded cells are exposed to the open-circuit voltage of the illuminated cells. With large systems such voltage may be very high so that the break-down voltage is easily passed. In the shaded cells a strong local heat production can occur (hot spot) which may result to local damage of the shaded cell. In the worst case, these hot spots may cause fire.

The most common remedy for preventing hot spots is the application of by-pass diodes that start conducting at a relative low voltage in one direction and that isolate in the other direction, as has been described in U.S. Pat. No. 5,223,044 and WO 2005/101511. However the application of by-pass diodes is expensive. Particularly with thin-film PV modules that have a relatively low break-down voltage (typical <8V) the number of cells that can be protected per by-pass diode is small, i.e. about less than 10 for thin film a-Si.

In the case of thin-film PV-modules, monolithic by-pass diodes can be made at the cost of a very complex process for series connection.

Another method is the application of so-called PV-shunts, as was described in US 2003/0159728. According to this method several modules that consist of series connected cells are connected in parallel. When one module is partly shaded the reverse voltage over the shaded cells is decreased with the voltage of the fully illuminated modules. However combined series and parallel connections decreases the system voltage and increases the system current and it limits the freedom of design of the system.

In EP 1 079 441 a method for adapting the IV characteristic of a partly shaded PV module was described. According to this method the cells are exposed to an increasing biased AC voltage until the current starts to increase. After the treatment the cells show a non-linear conduction that permits a shaded cell conducting the short-circuit current of the illuminated cells at a relatively low voltage. However this method depends on the presence of accidental spots in the PV cell where the non-linear conduction can be introduced. Moreover direct contact with all cells is necessary.

U.S. Pat. No. 5,810,945 describes a method of fabricating an electronic micropatterned device, in particular a solar cell, in which at least one of the electrodes is provided with a pattern. The problem of shading is not addressed in this reference.

Toet et al. (C. Toet et al., Thin solid films 296; (1977) 49-52) describes a two-step technique for the growth of polycrystalline silicon thin films on glass substrates. The problem of shading is not addressed.

Wohlgemuth et al. (J. Wohlgemuth and W. Herrmann, Hot spot test for crystalline silicon modules, Photovoltaic Specialists Conference, 2005, Piscataway, N.J., USA 3-7 Jan. 2005, IEEE, US, Jan. 3, 2005, pages 1062-1063) describes methods for performing hot spot tests. The prevention of the formation of hot spots is not discussed.

It is therefore an object of the present invention to provide a remedy for preventing hot spots that does not show any of the disadvantages mentioned above, and which can be applied in an easy and cheap manner. It was now found that this objective could be reached by adapting the IV characteristics of the thin-film PV cells by introducing identical well defined non-linear conducting spots at precisely defined positions. To this end the invention pertains to a photovoltaic (PV) module comprising a plurality of cells, each cell containing a substrate, a transparent conductor layer, a photovoltaic layer, and a back-electrode layer, wherein the photovoltaic layer comprises at least one p-i-n or n-i-p silicon layer, characterized in that said silicon layer comprises 10 to 1000 conducting spots of recrystallized silicon per cm², each having independently a surface of 10 to 2500 μm².

This method is based on the fact that most PV cells consist of an active semi-conductor layer having electrode layers on both sides. At least one of these electrode layers is transparent so that light may reach the active layer.

According to the invention the active layer of the PV cell is locally heated so that the layer transforms at least partly into another phase. The transformed material loses the PV characteristics but the semi-conductor properties can be preserved by carefully dosing the amount of heat. As a result the transformed spots act as non-linear conducting paths between the two electrode layers which have a relatively low conductivity at low voltage and a relatively high conductivity at high voltage. More in particular, the conductivity of the spots at a voltage of 1V is less than 0.2 mA/cm², while the conductivity at a voltage of 8V is more than 10 mA/cm².

In the present specification the transformed material will sometimes be indicated as recrystallized silicon, and the formation process will sometimes be indicated as melting followed by recrystallisation. However, this description should in no way be regarded as limiting the nature of the present invention. It will be clear that the crux of the present invention is the presence of conducting spots, and in their formation by way of heat treatment. It does not reside in the crystalline form of the silicium or in whether or not melting or recrystallisation takes place.

In order to minimize local heat production many of such non-linear conducting spots must be made so that the current per spot is small.

The current through the non-linear conducting spots can be described as with an odd series expansion:

$${J}_{conducting spots} ( V ) = \frac{V}{{R}_{1}} + \frac{{V}^{3}}{{R}_{3}} + \frac{{V}^{5}}{{R}_{5}} + … \qquad ( 1 )$$

Wherein J_{conducting spots} (V) is the current per unit of surface through the conducting spots at the voltage V [A/cm²]; V is the voltage between the two electrodes [V]; and 1/Rₙ is the nth order coefficient of the series expansion. The dimension of Rₙ is [Vⁿ.cm²/A].

The part directly around a voltage V=0 is determined mostly by R₁, the next part also by R₃, etc. For the description of the essential part of the JV curve of a PV cell the coefficients R₁ and R₃ are sufficient. R₁ must be as high as possible because the linear conduction starts causing losses at a low voltage. R₃ must be chosen so that the maximum possible current is conducted at a voltage below the break-down voltage.

Without the introduction of the non-linear conducting spots the reverse voltage over a shaded cell may be as high as −19V in the case of a module with 28 cells when the module is shorted (R₁=10,000, R₃=1,000,000). With a larger number of cells the reverse voltage over the shaded cell increases. That large voltage is far beyond the break down voltage. With the non-linear conducting spots (R₁=2,500, R₃=10,000) the voltage over a shaded cell is limited to −5V which is below the break-down voltage. R₁ shows a related decrease with the introduction of R₃. The JV curve under normal conditions (no shading) is hardly affected by the non-linear conducting spots. With an increasing number of cells the reverse voltage over a shaded cell remains about −5V when the module is shorted.

When non-linear conducting spots are applied in all cells of a module so that the p-i-n or n-i-p silicon layer comprises 10 to 1000 conducting spots of recrystallized silicon per cm², each having independently a surface of 10 to 2500 μm², shading does not cause damage regardless the number of series connected cells. Because a large number of regular distributed conducting spots is introduced, the dissipated energy in the shaded cell is also regularly distributed over the PV cell. Excessive heating of a single spot is avoided. The module performance under normal conditions is hardly affected by the non-linear conducting spots.

In a preferred embodiment the PV module has a silicon layer comprising 20 to 500 conducting spots per cm², more preferably 30 to 300 conducting spots per cm², still more preferably 80 to 120 conducting spots per cm². In another preferred embodiment the PV module has a silicon layer wherein the conducting spots have a surface of 30 to 300 μm², preferably 50 to 150 μm², more preferably 60 to 120 μm².

Because the spots do not contribute to current production under normal operating conditions, it is preferred for the total surface area of the conductive spots to be relatively small. More in particular, the ratio of the surface area of the conductive spots to the surface area of the current generating part or the solar cell preferably is less than 0.01:1, more preferably less than 0.001:1, As a preferred minimum value, a ratio of 0.00001:1 may be mentioned.

It is another objective of the invention to provide a method for making the above PV modules. Non-linear conducting spots can be obtained in several ways. One way is obtaining non-linear spots by applying an increasing AC voltage over the cells that are directly contacted with long electrodes. However by doing so the spots are randomly distributed and properties of the spots depend on accidental local conditions of the active layer of the PV cell.

Well defined spots are obtained by bringing a defined amount of energy to the active layer of the PV cell at defined positions. According to a preferred method the p-i-n or n-i-p silicon layer is locally heated at 10 to 1000 spots per cm², each spot having independently a surface of 10 to 2500 μm², whereby said silicon is transformed at least partly to another phase at these spots. For instance, this can be carried out with the focused beam of a pulsed laser of which the wavelength is such that it is absorbed in the active layer of the PV cell. With amorphous Si PV cells a frequency doubled Q-switched Nd-YAG, Nd-YFL or Nd-YVO4 laser can be used (λ=532 nm). The pulse duration of such lasers is short, typical less than 50 ns (nanoseconds), more typically about 15 ns, so that the directly illuminated spot absorbs all energy without losses due to heat conduction. The pulse energy is constant within a narrow range and the diameter of the beam waist in the focus point can be small according to:

$$d = \frac{1.22 \cdot λ \cdot F}{D} \qquad ( 2 )$$

wherein d is the diameter of the beam waist;
λ is the wavelength of the laser light;
F is the focal length of the focusing lens; and
D is the diameter of the parallel laser beam before entering the lens

With D=5 mm, F=100 mm and λ=532 nm it follows that d=13 μm. In the waist the laser beam has a Gaussian intensity profile so that the sizes of the non-linear spots that are made with the laser are even smaller.

The invention is further illustrated by the following non-limitative description of a specific embodiment of the invention.

Small sized modules (8 cells of 1×7.5 cm²) and larger modules (28 cells of 1×30 cm²) were treated with a pulsed. ND-YVO4 laser. A single row of non-linear conducting spots (distance between 2 spots 50 μm) per cell was made.

The laser treatment introduces a non-linear conductance of the cells that can be characterized with the values of Rₙ of eq. (1). A method for determining Rₙ is described below. The JV-curves of single cells can be described with the well-know diode equation (see S. R. Wenham et al., Applied Photovoltaics, ISBN 0 86758 909 4, p. 33) which equation is extended with terms for the light induced current and the non-linear parallel resistance:

$$J = {J}_{0} \cdot ( {e}^{\frac{q V}{n k T}} - 1 ) - {J}_{L} + \frac{V}{{R}_{1}} + \frac{{V}^{3}}{{R}_{3}} + … \qquad ( 3 )$$

wherein J is the current density [A/m²]
J₀ is the dark current density [A/m²]
J_{L} is the light induced current density [A/m²]
q is elementary charge
k is the Boltzmann constant
n is the diode quality factor
T is the temperature [K]
V is the voltage per cell

The JV curve of a fully illuminated module is only slightly sensitive for varying values of Rₙ of normal cells. When one of the cells is shaded the JV-curve changes strongly. The light induced current of the shaded cell is (almost) zero. The illuminated cells apply a reverse voltage over the shaded cell that is varied with the external voltage source. The shaded cell acts as sort of load resistance for the illuminated, cells of the module. The theoretical JV curves of the illuminated cells are insensitive for Rₙ when the cells are not strongly shunted. On the contrary the JV curve of the shaded cell is strongly dependent on R, and so is the JV curve of a module with one shaded cell.

First the JV curve of the fully illuminated module is measured. The average cell parameters including R, are determined from that curve. Next the JV curve of the module is recorded while shading one cell. The values of R, of the shaded cell are obtained with a curve fitting procedure. The light induced current of the shaded cell J_{L, shaded cell}=0 and only R, of the shaded cell must be adapted for obtaining a proper fit. The average values of R₁ and R₃ and the values of R₁ and R₃ of the shaded cell that result from the fitting procedure are listed in Table 1.

TABLE 1
Values of R₁ and R₃ that are derived from the curve
fitting procedure

| | R_{1,average} | R_{3,average} | R_{1,cell 4} | R_{3,cell 4} |
|---|---|---|---|---|
| Before Laser | 20,000 | 2,000,000 | 6,000 | 66,000 |
| treatment | | | | |
| After Laser | 3,500 | 20,000 | 2,500 | 13,500 |
| treatment | | | | |

The decrease of the average value of R₁ is realistic, that of the average value of R₃ is more or less arbitrarily because the calculated curve of the fully illuminated module is hardly influenced by that value. The decrease of R₁ and R₃ of the shaded cell are determined with acceptable accuracy. R₅ does not play an important role for fitting the relevant part of the JV curves as long as the value of R₅ is chosen sufficiently large.

The values of R₁ and R₃ of the individual cells can be used for characterizing the quality of the laser treatment process A range of values for proper operating cells can be defined for both parameters: R₁>1000, in particular R₁>2000; 1000<R₃<50000, in particular 10000<R₃<50000 (those values may be changed).

Table 2 shows J-V curves of an eight cells module. The first column gives the module voltage. The second and third columns give the module current and the voltage over one cell respectively versus the module voltage (without shading). The fourth and the fifth columns give the module current and the voltage over the shaded standard cell versus the module voltage one cell shaded). The sixth and the seventh columns give the module current and the voltage over the shaded cell with conducting spots versus the module voltage (one cell shaded).

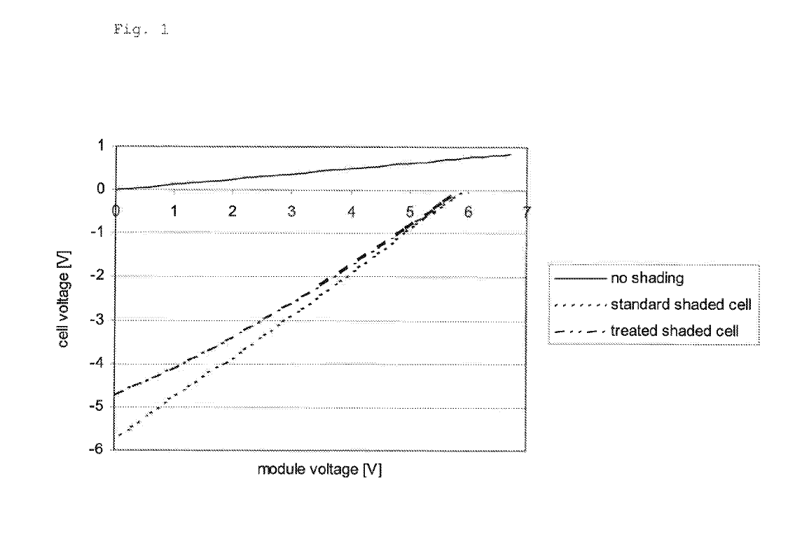

FIG. 1 gives a graphical representation of the voltage of a single cell versus the voltage of an eight cell module (numerical data given in Table 2).

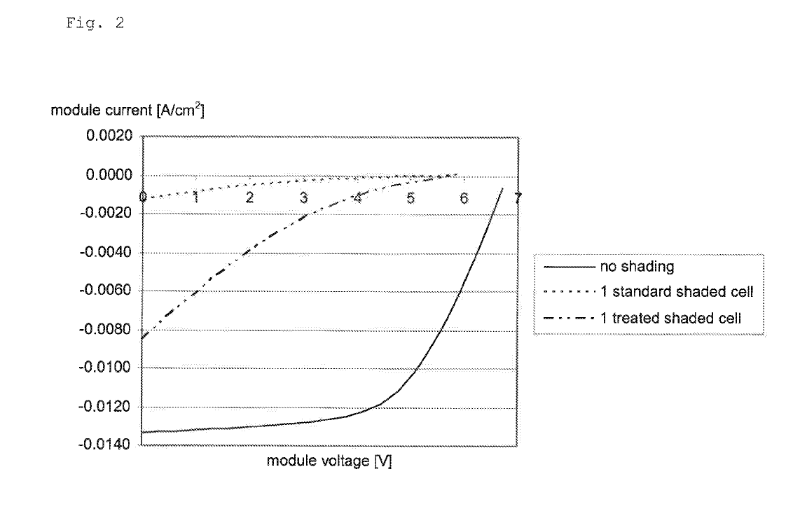

FIG. 2 gives the JV curves of the eight cell module, showing the current of the module versus the voltage of the module (numerical data given in Table 2).

It is obvious that the reverse voltage over a shaded cell with the conducting spots is limited whereas the voltage over a shaded standard cell increases almost linearly with the module voltage.

TABLE 2

| | | | not treated | | treated | |
|---|---|---|---|---|---|---|
| | no cells shaded | | one cell shaded | | one cell shaded | |
| | J | V_{cell} | J | V_{sh Cell} | J | V_{sh cell} |
| V_{module} | [A/cm²] | [V] | [A/cm²] | [V] | [A/cm²] | [V] |
| 0 | −0.01333 | 0.000 | −0.00133 | −5.753 | −0.00858 | −4.72066 |
| 0.32 | −0.01329 | 0.040 | −0.00116 | −5.445 | −0.00777 | −4.53519 |
| 0.64 | −0.01325 | 0.080 | −0.00101 | −5.136 | −0.00697 | −4.33839 |
| 0.96 | −0.01321 | 0.120 | −0.00088 | −4.826 | −0.00619 | −4.13143 |
| 1.28 | −0.01316 | 0.160 | −0.00076 | −4.515 | −0.00545 | −3.91506 |
| 1.6 | −0.01311 | 0.200 | −0.00065 | −4.203 | −0.00474 | −3.68978 |
| 1.92 | −0.01305 | 0.240 | −0.00054 | −3.964 | −0.00407 | −3.45636 |
| 2.24 | −0.01299 | 0.280 | −0.00045 | −3.654 | −0.00346 | −3.21435 |
| 2.56 | −0.01292 | 0.320 | −0.00037 | −3.343 | −0.0029 | −2.96425 |
| 2.88 | −0.01284 | 0.360 | −0.0003 | −3.030 | −0.00239 | −2.70627 |
| 3.2 | −0.01274 | 0.400 | −0.00025 | −2.715 | −0.00194 | −2.44065 |
| 3.52 | −0.01262 | 0.440 | −0.0002 | −2.397 | −0.00154 | −2.16766 |
| 3.84 | −0.01246 | 0.480 | −0.00015 | −2.078 | −0.0012 | −1.88769 |
| 4.16 | −0.01221 | 0.520 | −0.00012 | −1.755 | −0.00091 | −1.60124 |
| 4.48 | −0.0118 | 0.560 | −8.4E−05 | −1.431 | −0.00067 | −1.30893 |
| 4.8 | −0.01113 | 0.600 | −5.7E−05 | −1.105 | −0.00047 | −1.01159 |
| 4.96 | −0.01067 | 0.620 | −4.6E−05 | −0.942 | −0.00039 | −0.86132 |
| 5.12 | −0.01012 | 0.640 | −3.6E−05 | −0.780 | −0.00031 | −0.71015 |
| 5.28 | −0.00947 | 0.660 | −2.7E−05 | −0.620 | −0.00023 | −0.55822 |
| 5.44 | −0.00874 | 0.680 | −1.6E−05 | −0.465 | −0.00017 | −0.40568 |
| 5.6 | −0.00792 | 0.700 | −3.5E−06 | −0.311 | −0.0001 | −0.25265 |
| 5.76 | −0.00704 | 0.720 | 9.18E−06 | −0.157 | −3.9E−05 | −0.09932 |
| 5.92 | −0.00609 | 0.740 | 2.08E−05 | −0.005 | | |
| 6.08 | −0.00508 | 0.760 | | | | |
| 6.24 | −0.00402 | 0.780 | | | | |
| 6.4 | −0.00292 | 0.800 | | | | |
| 6.56 | −0.00177 | 0.820 | | | | |
| 6.72 | −0.00059 | 0.840 | | | | |

1. Photovoltaic (PV) module comprising a plurality of cells, each cell containing a substrate, a transparent conductor layer, a photovoltaic layer, and a back-electrode layer, wherein the photovoltaic layer comprises at least one p-i-n or n-i-p silicon layer, and said silicon layer comprises 10 to 1000 conducting spots of recrystallized silicon per cm², each having independently a surface of 10 to 2500 μm².

2. The PV module of claim 1 wherein the silicon layer comprises 20 to 500 conducting spots per cm².

3. The PV module of claim 1, wherein the conducting spots have a surface of 30 to 300 μm².

4. A method for making the PV module of claim 1 wherein the p-i-n or n-i-p silicon layer is locally heated at 10 to 1000 spots per cm², each spot having independently a surface of 10 to 2500 μm², whereby the p-i-n or n-i-p silicon is transformed at these spots to form conductive spots.

5. The method according to claim 4 wherein the heating is performed by a pulsed laser.

6. The method according to claim 5 wherein the heating is performed by a frequency doubled Nd-YAG, Nd-YLF, or Nd-VO4 laser with a wavelength λ between 520 and 550 nm and a pulse duration less than 50 ns.

7. The PV module of claim 2, wherein the conducting spots have a surface of 30 to 300 μm².

8. A method for making the PV module of claim 2, wherein the p-i-n or n-i-p silicon layer is locally heated at 10 to 1000 spots per cm², each spot having independently a surface of 10 to 2500 μm², whereby the p-i-n or n-i-p silicon is transformed at these spots to form conductive spots.

9. A method for making the PV module of claim 3, wherein the p-i-n or n-i-p silicon layer is locally heated at 10 to 1000 spots per cm², each spot having independently a surface of 10 to 2500 μm², whereby the p-i-n or n-i-p silicon is transformed at these spots to form conductive spots.

10. A method for making the PV module of claim 7, wherein the p-i-n or n-i-p silicon layer is locally heated at 10 to 1000 spots per cm², each spot having independently a surface of 10 to 2500 μm², whereby the p-i-n or n-i-p silicon is transformed at these spots to form conductive spots.

11. The method according to claim 8, wherein the heating is performed by a pulsed laser.

12. The method according to claim 9, wherein the heating is performed by a pulsed laser.

13. The method according to claim 10, wherein the heating is performed by a pulsed laser.

14. The method according to claim 11, wherein the heating is performed by a frequency doubled Nd-YAG, Nd-YLF, or Nd-VO4 laser with a wavelength λ between 520 and 550 nm and a pulse duration less than 50 ns.

15. The method according to claim 12, wherein the heating is performed by a frequency doubled Nd-YAG, Nd-YLF, or Nd-VO4 laser with a wavelength λ between 520 and 550 nm and a pulse duration less than 50 ns.

16. The method according to claim 10, wherein the heating is performed by a frequency doubled Nd-YAG, Nd-YLF, or Nd-VO4 laser with a wavelength λ between 520 and 550 nm and a pulse duration less than 50 ns.
